(19) United States
(12) Patent Application Publication
(10) Pub. No.: US 2009/0058900 A1
(43) Pub. Date: Mar. 5, 2009

(54) PULSE GENERATION APPARATUS, IMAGE FORMATION APPARATUS, AND PULSE GENERATION METHOD

(75) Inventors: Noritaka IDE, Shiojiri-shi (JP); Toshiyuki SUZUKI, Shiojiri-shi (JP)

Correspondence Address: Workman Nydegger;1000 Eagle Gate Tower, 60 East South Temple, Salt Lake City, UT, 84111, US

(73) Assignee: SEIKO EPSON CORPORATION, Tokyo (JP)

(21) Appl. No.: 12/199,910

(22) Filed: Aug. 28, 2008

(30) Foreign Application Priority Data
Aug. 29, 2007 (JP) 2007-222734

(51) Int. Cl. B41J 29/38; H03L 7/00

(52) U.S. Cl. 347/9; 327/141

(57) ABSTRACT

A pulse generation apparatus has an encoder that outputs an encoder signal in a cycle corresponding to each driven operation of a driving target medium by a drive amount per unit. The pulse generation apparatus generates a pulse on the basis of the encoder signal that is outputted by the encoder. The amplitude of the signal changes in a cyclic manner. The pulse generation apparatus has a switching unit that receives the encoder signal and then switches either the amplitude of the signal or a threshold depending on the driven speed of the driving target medium so as to change the number of signal waves that exceed the threshold depending on the driven speed of the driving target medium. The pulse generation apparatus also has a pulse generating unit that generates a pulse having the same cycle as that of the signal wave that exceeds the threshold.

### BACKGROUND

1. Technical Field

The present invention relates to a pulse generation apparatus that generates a pulse on the basis of a signal that is outputted from an encoder. The encoder outputs a signal that has a cycle corresponding to the driven speed of a driving target medium. In addition, the present invention further relates to an image formation apparatus that is provided with such a pulse generation apparatus, and a pulse generation method having the same features as above.

2. Related Art

An image formation apparatus such as a printer is typically provided with a recording head. The recording head ejects ink onto a sheet of printing paper that is fed in a paper-transport direction. In such a printing process, it is necessary to discharge each ink drop with appropriate timing in accordance with the position of the sheet of printing paper that is now being transported. For this reason, a print reference signal is generated for controlling ink-ejection timing. The print reference signal is generated in accordance with the transport speed of the sheet of printing paper on the basis of a signal outputted from an encoder. The encoder outputs a signal in synchronization with the paper-transport speed.

As an example of an image formation apparatus of the related art, a printer that is provided with a paper-transport belt is described in JP-A-2006-96429 (refer to Paragraphs [0023] and [0024] of the specification as well as FIG. 1 thereof). The paper-transport belt is provided as a paper-transporting member/unit. In the configuration of such an image formation apparatus of the related art, the paper-transport belt constitutes a driving target medium. Detection targets such as light-transmitting portions or light-shielding portions are formed on the paper-transport belt for detecting the speed and the position thereof. An encoder detects these targets and then outputs an encoder signal. A recording head ejects ink on the basis of the encoder signal. By this means, the printer described in the above-identified JP-A-2006-96429 outputs images, characters, and the like on a sheet of printing paper. Some image formation apparatuses have a magnetic linear encoder. An example thereof is described in JP-A-5-318869 (refer to Paragraphs [0014], [0015], and [0016] of the specification as well as FIGS. 2, 5, 10, and 11 thereof).

Typically, in the case of a magnetic linear encoder, polarization is performed on the magnetic linear scale thereof at regular intervals. For this reason, it is only at regular intervals that a positional signal is obtained. Since the data transfer speed of a printing apparatus is typically limited, a plurality of printing modes is provided so as to correspond to the traveling speed (i.e., operation speed) of a belt. For example, the belt operation speed is set relatively high at the time when high-speed printing such as draft printing is performed while decreasing print resolution. On the other hand, the belt operation speed is set relatively low for low-speed (i.e., high-quality) printing such as photo printing while increasing print resolution.

For example, the above-identified JP-A-5-318869 discloses a serial recording apparatus that is provided with a magnetic linear encoder having two or more polarization lines. These two or more polarization lines, which are formed on the magnetic linear scale thereof, have polarization pitches that differ from each other or one another. With such a plurality of polarization lines, the serial printer described in JP-A-5-318869 offers a plurality of printing modes. Since the serial printer described in JP-A-5-318869 is provided with two or more polarization lines that have polarization pitches different from each other or one another, it is possible to achieve two or more resolutions.

Disadvantageously, however, if the configuration of the serial printer described in JP-A-5-318869 is adopted, two or more magnetic sensors are required because of the increased number of the polarization lines, which increases cost. As another disadvantage thereof, it is necessary to secure a space equal to the width of each polarization line multiplied by the number of polarization lines. Note that these disadvantages are not unique to magnetic linear encoders. The same holds true for optical linear encoders.

### SUMMARY

An advantage of some aspects of the invention is to provide a pulse generation apparatus that is capable of generating, with a simple structure, a pulse that offers different resolutions depending on the driven speed of a driving target medium. In addition, the invention provides, as an advantage of some aspects thereof, an image formation apparatus that is provided with such a pulse generation apparatus, and a pulse generation method having the same features as above.

In order to address the above-identified problem without any limitation thereto, the invention provides, as a first aspect thereof, a pulse generation apparatus that includes: an encoder that outputs an encoder signal in a cycle corresponding to each driven operation of a driving target medium by a drive amount per unit, the pulse generation apparatus generating a pulse on the basis of the encoder signal that is outputted by the encoder, the amplitude of the signal changing in a cyclic manner; a switching section that receives the encoder signal that is outputted from the encoder and then switches at least either one of the amplitude of the signal and a threshold depending on the driven speed of the driving target medium so as to change the number of signal waves that exceed the threshold depending on the driven speed of the driving target medium; and a pulse generating section that generates a pulse having the same cycle as that of the signal wave that exceeds the threshold.

In the configuration of a pulse generation apparatus according to the first aspect of the invention described above, an encoder outputs an encoder signal in a cycle corresponding to each driven operation of a driving target medium by a drive amount per unit. A switching section receives the encoder signal that is outputted from the encoder and then switches at least either one of the amplitude of the signal and a threshold depending on the driven speed of the driving target medium. By this means, the switching section changes the number of signal wave(s) that exceed the threshold depending on the driven speed of the driving target medium. A pulse generating section generates a pulse having the same cycle as that of the signal wave that exceeds the threshold. Therefore, a pulse generation apparatus according to the first aspect of the invention is capable of generating, with a simple structure, a pulse that offers different resolutions depending on the driven speed of the driving target medium.

In the configuration of a pulse generation apparatus according to the first aspect of the invention described above, it is preferable that the switching section should be a filtering section whose cutoff frequency is set in such a manner that signal-output gain changes in accordance with the frequency of the signal; and the signal that is outputted from the encoder should pass through the filtering section so that the amplitude of the signal is switched over depending on the driven speed of the driving target medium.

In such a preferred configuration of a pulse generation apparatus according to the first aspect of the invention, the frequency of the signal that is inputted into the filtering section, which is the switching section, is proportional to the driven speed of the driving target medium. The cutoff frequency of the filtering section is set in such a manner that signal-output gain changes in accordance with the frequency of the signal. Therefore, the signal has a low frequency when the driving target medium is driven in a low speed, whereas the signal has a high frequency when the driving target medium is driven in a high speed. The gains of signal output differ depending on the difference in frequency. Therefore, a signal having amplitude that corresponds to the signal-output gain is outputted. That is, signal amplitude is switched over depending on the driven speed of the driving target medium.

In the preferred configuration of a pulse generation apparatus described above, it is further preferable that the filtering section should have such a circuit constant that the signal-output gain changes gradually in accordance with the driven speed of the driving target medium at a change region; and at least either one of the minimum driven speed of the driving target medium and the maximum driven speed of the driving target medium should be set in the change region.

In such a preferred configuration, at least either one of the minimum driven speed of the driving target medium and the maximum driven speed of the driving target medium is set in the change region. Therefore, the passing of the encoder output signal through the filtering section makes it possible to achieve different amplitudes depending on the driven speed of the driving target medium.

In the preferred configuration of a pulse generation apparatus described above, it is further preferable that the filtering section should have such a cutoff frequency that the signal-output gain obtained at the time of the high-speed driven operation (i.e., frequency) of the driving target medium is larger than the signal-output gain obtained at the time of the low-speed driven operation (i.e., frequency) of the driving target medium.

In such a preferred configuration, since the filtering section has such a cutoff frequency that the signal-output gain obtained at the time of the high-speed driven operation (i.e., frequency) of the driving target medium is larger than the signal-output gain obtained at the time of the low-speed driven operation (i.e., frequency) of the driving target medium, the amplitude of the signal decreases as the driven speed of the driving target medium increases. As a result thereof, a larger number of signal waves that do not exceed the threshold are “decimated” (e.g., skipped). For this reason, a pulse is generated in such a manner that the drive amount of the driving target medium for each one cycle of the pulse is relatively large.

In the configuration of a pulse generation apparatus according to the first aspect of the invention described above, it is preferable that the switching section should be a threshold switching section that switches the threshold depending on the driven speed of the driving target medium. In such a preferred configuration of a pulse generation apparatus according to the first aspect of the invention, the threshold switching section switches the threshold depending on the driven speed of the driving target medium. Since the threshold switching section performs a threshold switchover, the number of signal waves that exceed the threshold under the low-speed driven operation of the driving target medium differs from the number of signal waves that exceed the threshold under the high-speed driven operation of the driving target medium. Therefore, it is possible to easily generate a pulse that achieves different drive amounts of the driving target medium per one pulse output depending on the driven speed of the driving target medium.

In the configuration of a pulse generation apparatus according to the first aspect of the invention described above, it is preferable that the encoder should be a magnetic encoder that has a magnetic scale and a magnetic sensor; a polarization pattern whose magnetic field intensity changes in a cyclic manner should be formed on the magnetic scale; and the magnetic sensor should perform magnetic detection on the magnetic scale and then should output an encoder signal including signal waves whose amplitudes correspond to the magnetic field intensity of the polarization pattern.

In such a preferred configuration of a pulse generation apparatus according to the first aspect of the invention, the magnetic scale and the magnetic sensor move relative to each other as a result of the driven operation of the driving target medium. The magnetic sensor performs magnetic detection on the magnetic scale and then outputs an encoder signal including signal waves whose amplitudes correspond to the magnetic field intensity of the polarization pattern. Since the polarization pattern is formed in such a manner that the magnetic field intensity thereof changes in a cyclic manner, it is possible to cause the encoder to output an encoder signal containing signal waves whose amplitudes change in a cyclic manner.

In order to address the above-identified problem without any limitation thereto, the invention provides, as a second aspect thereof, an image formation apparatus that includes: a transporting section that transports an image-formation target medium; a recording section that performs recording on the image-formation target medium; and the pulse generation apparatus according to the first aspect of the invention, wherein the encoder that makes up a part of the pulse generation apparatus is capable of detecting either the transport of the transporting section or the movement of the recording section; and the image formation apparatus uses a pulse that is outputted from the pulse generation apparatus as a reference signal for determining the recording timing of the recording section.

In the configuration of an image formation apparatus according to the second aspect of the invention described above, the encoder is capable of detecting either the transport of the transporting section or the movement of the recording section. The pulse generation apparatus outputs a pulse that achieves different drive amounts of the transporting section or the recording section per one pulse output depending on the transport speed of the transporting section or the movement speed of the recording section. The recording section performs recording on the image-formation target medium on the basis of a pulse that is received from the pulse generation apparatus as a reference signal for determining the recording timing. Therefore, an image formation apparatus according to the second aspect of the invention described above can perform recording with different resolutions depending on the transport speed of the transporting section or the movement speed of the recording section.

In order to address the above-identified problem without any limitation thereto, the invention provides, as a third aspect thereof, a pulse generation method for generating a pulse on the basis of an encoder signal that is outputted by an encoder, the encoder outputting the encoder signal in a cycle corresponding to each driven operation of a driving target medium by a drive amount per unit, the pulse generation method including: inputting the signal whose amplitude changes in a cyclic manner from the encoder; switching at least either one of the amplitude of the signal and a threshold depending on the driven speed of the driving target medium so as to change the number of signal waves that exceed the threshold depending on the driven speed of the driving target medium; and generating a pulse that has the same cycle as that of the signal wave that exceeds the threshold. With such a pulse generation method, the same advantageous effects as those offered by the pulse generation apparatus according to the first aspect of the invention described above are obtained.

### BRIEF DESCRIPTION OF THE DRAWINGS

The invention will be described with reference to the accompanying drawings, wherein like numbers reference like elements.

FIG. 1 is a plan view that schematically illustrates an example of the configuration of an ink-jet recording apparatus (printer) according to a first exemplary embodiment of the invention.

FIG. 2 is a side view that schematically illustrates an example of the configuration of the ink-jet recording apparatus shown in FIG. 1.

FIG. 3 is a diagram that explains an example of a method for polarizing the magnetic linear scale of a magnetic linear encoder according to the first exemplary embodiment of the invention.

FIG. 4 is a two-part diagram that schematically illustrates an example of the intensity (i.e., strength) of a magnetic field that works on, or is applied to, the magnetic recording layer at the time of the polarization performed with the use of a magnetic recording head; and in addition thereto, FIG. 4 further schematically illustrates an example of the magnetic state (line of magnetic induction) of a magnetic linear scale.

FIG. 5 is a block diagram that schematically illustrates an example of the electric configuration of the print controlling system inside a controller according to the first exemplary embodiment of the invention.

FIG. 6 is a block diagram that schematically illustrates an example of the inner configuration of a signal generation circuit according to the first exemplary embodiment of the invention.

FIG. 7 is an electric circuit diagram that schematically illustrates an example of the circuit configuration of the signal generation circuit according to the first exemplary embodiment of the invention.

FIG. 8 is a graph that shows an example of the relationship between a belt operation/traveling speed and an encoder output gain according to the first exemplary embodiment of the invention.

FIG. 9 is a diagram/graph that schematically illustrates an example of the relationship between the signal strength of a filter-output encoder signal at the time of low-speed belt operation and a print reference pulse according to the first exemplary embodiment of the invention.

FIG. 10 is a diagram/graph that schematically illustrates an example of the relationship between the signal strength of a filter-output encoder signal at the time of high-speed belt operation and a print reference pulse according to the first exemplary embodiment of the invention.

FIG. 11 is an electric circuit diagram that schematically illustrates an example of the circuit configuration of a signal generation circuit according to a second exemplary embodiment of the invention.

FIG. 12 is a diagram/graph that schematically illustrates an example of the relationship between the signal strength of an encoder signal at the time of high-speed belt operation and a print reference pulse according to the second exemplary embodiment of the invention.

### DESCRIPTION OF EXEMPLARY EMBODIMENTS

### First Embodiment

With reference to FIGS. 1-10, a pulse generation apparatus, an image formation apparatus, and a pulse generation method according to a first exemplary embodiment of the invention is explained below.

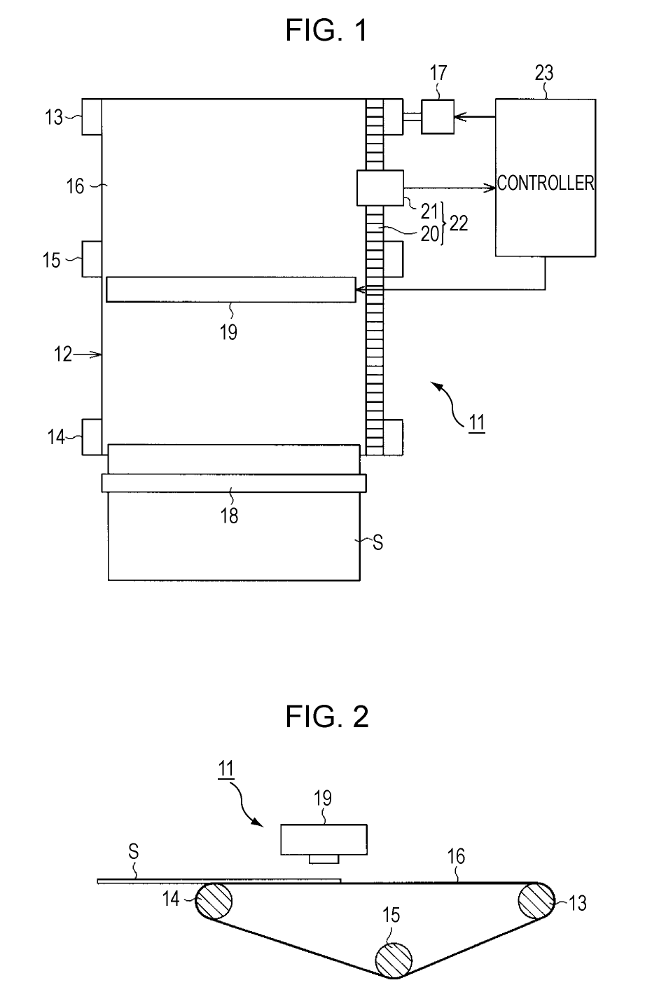

FIG. 1 is a plan view that schematically illustrates an example of the configuration of an ink-jet recording apparatus according to an exemplary embodiment of the invention. FIG. 2 is a side view that schematically illustrates an example of the configuration of the ink-jet recording apparatus shown in FIG. 1. The lower side of FIG. 1 corresponds to the upstream side of a paper-transport channel/route when viewed along the direction of paper transportation.

As illustrated in FIGS. 1 and 2, an ink-jet recording apparatus according to the present embodiment of the invention is provided with a belt paper-transport device 12, which transports a sheet of printing paper S. The ink-jet recording apparatus that is described in the present embodiment of the invention is a non-limiting example of an “image formation apparatus” according to an aspect of the invention. In the following description, the ink-jet recording apparatus is simply referred to as a printer 11. The belt paper-transport device 12 is mainly made up of a paper-transport driving roller (i.e., master roller) 13, a paper-transport driven roller (i.e., slave roller) 14, a tension roller 15, and an endless paper-transport belt 16. The paper-transport driving roller 13 is provided at a (relatively) downstream-side position of a paper-transport channel/route when viewed along the direction of paper transportation. On the other hand, the paper-transport driven roller 14 is provided at an (relatively) upstream-side position of the paper-transport channel/route when viewed along the direction of paper transportation. As shown in FIG. 2, the tension roller 15 is provided at substantially the center, for example, near the center, between the paper-transport driving roller 13 and the paper-transport driven roller 14. As further illustrated therein, the tension roller 15 is provided slightly below the paper-transport driving roller 13 and the paper-transport driven roller 14. The endless paper-transport belt 16 is wound around the paper-transport driving roller 13, the paper-transport driven roller 14, and the tension roller 15.

The motor power transmission axis (i.e., driving force output axis) of an electric motor 17 is either directly or indirectly connected to the paper-transport driving roller 13. In the latter case, the driving force output axis of the electric motor 17 is interlocked with the paper-transport driving roller 13 with a speed reduction mechanism being interposed therebetween. Note that such a speed reduction mechanism is not shown in the drawing. With such a structure, the driving force of the electric motor 17 can be transmitted (i.e., communicated) to the paper-transport driving roller 13. As the electric motor 17 turns in the normal direction, the paper-transport driving roller 13 also turns. Because of the rotation of the paper-transport driving roller 13, the endless paper-transport belt 16 turns in a direction along which a sheet of printing paper S is transported from the upstream side to the downstream side. A gate roller 18 is provided at a certain upstream-side position on the belt paper-transport device 12. A sheet of printing paper S is fed onto the endless paper-transport belt 16 as a result of the rotation of the gate roller 18. The sheet of printing paper S is brought into contact with the roller surface of the gate roller 18 for skew correction thereof. The gate roller 18 feeds out each sheet of printing paper S in synchronization with drive-start timing so as to set the sheet of printing paper S at a target position on the endless paper-transport belt 16.

A recording head 19 is provided over the endless paper-transport belt 16 at a certain middle position thereof when viewed along the direction of paper transportation. The recording head 19 is configured as a line head that has an elongated head body. The elongated recording head 19 that is formed as a line head is oriented in the width direction of the endless paper-transport belt 16. That is, the elongated line-type recording head 19 is provided in parallel with the width of the endless paper-transport belt 16. The recording head 19 has nozzle line(s) on the lower surface thereof. Each nozzle line is made up of a number of nozzles that are arrayed with a predetermined nozzle pitch. A large number of nozzles that make up each nozzle line are arrayed so as to have a line length that is larger than the width of the maximum sheet size of printing paper S on which the printer 11 can perform printing. That is, these nozzles are arrayed in a width-directional line area that is greater in length than the width-directional maximum sheet size of printing paper S on which the printer 11 can perform printing. The recording head 19 ejects ink drops from/through these nozzles in a sequential manner in accordance with a paper-transport speed (e.g., in synchronization with paper-transport operation) while transporting a sheet of printing paper S. In this way, the printer 11 outputs (i.e., prints out) an image and the like on the sheet of printing paper S.

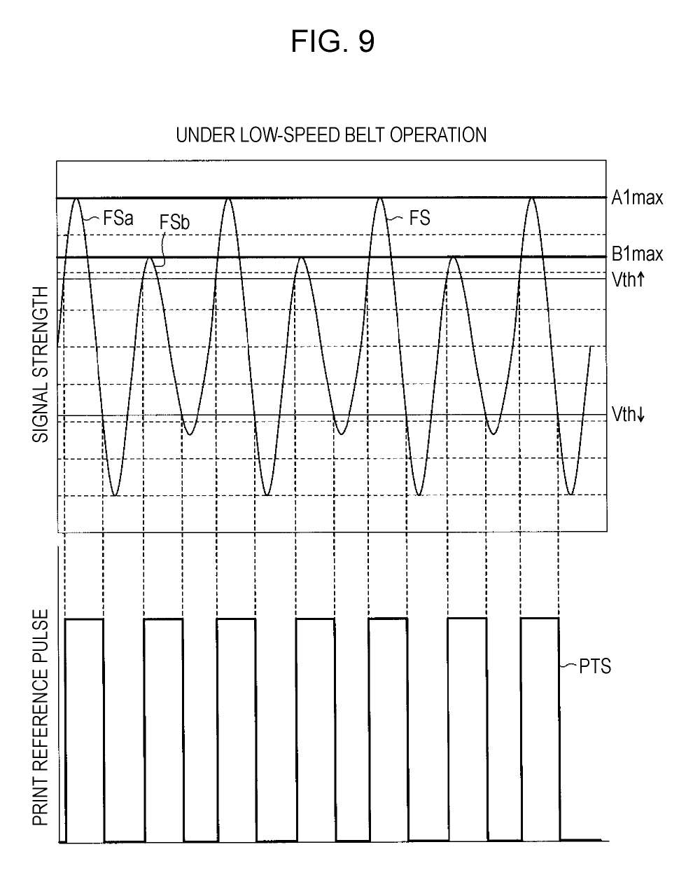

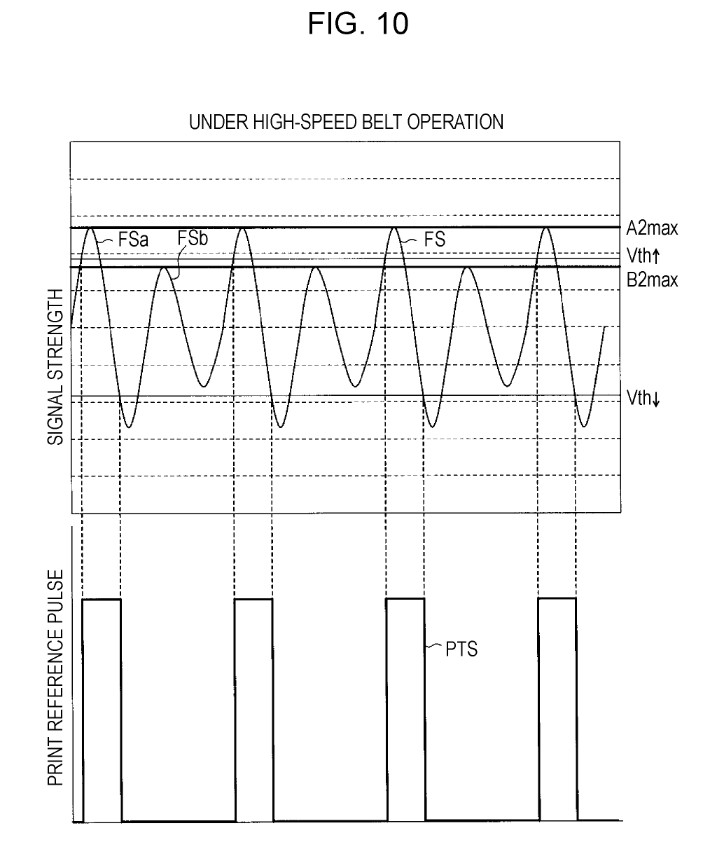

A magnetic linear scale 20 is formed at an edge portion of the endless paper-transport belt 16. More specifically, the magnetic linear scale 20 is formed throughout the entire circumference of the endless paper-transport belt 16 stretched along the paper-transport direction. The magnetic linear scale 20 is formed as a strip-shaped magnetic recording layer with a magnetic pattern being formed thereon. The tape-like magnetic recording layer is formed at the edge portion of the endless paper-transport belt 16. The magnetic pattern is recorded on the magnetic recording layer with a predetermined pitch. A magnetic sensor 21 is provided over the magnetic linear scale 20. In the exemplary configuration of the printer 11 illustrated in FIG. 1, the magnetic sensor 21 is provided at the near (i.e., proximal) side when viewed in a direction perpendicular to the sheet of FIG. 1, whereas the magnetic linear scale 20 is provided at the distant (i.e., distal) side when viewed in a direction perpendicular to the sheet of FIG. 1. The magnetic linear scale 20 and the magnetic sensor 21 are provided in proximity to each other. The magnetic sensor 21 reproduces (e.g., reads out, though not limited thereto) the magnetic pattern that is recorded on the magnetic linear scale 20. The magnetic linear scale 20 and the magnetic sensor 21 make up a magnetic linear encoder 22 according to the present embodiment of the invention. The printer 11 is provided with a controller 23, which functions as controlling means. The controller 23 controls the driving operation of the electric motor 17. In addition, upon reception of an encoder signal ES, which is inputted from the magnetic sensor 21 of the magnetic linear encoder 22, the controller 23 generates a print reference pulse PTS (i.e., ejection timing reference signal) inside an inner circuit thereof on the basis of the received encoder signal ES. An example of the print reference pulse PTS is shown in FIGS. 9 and 10. On the basis of the generated print reference pulse PTS, the controller 23 controls the ejection of ink drops at appropriate timing in accordance with the paper-transport speed (i.e., paper-transport position).

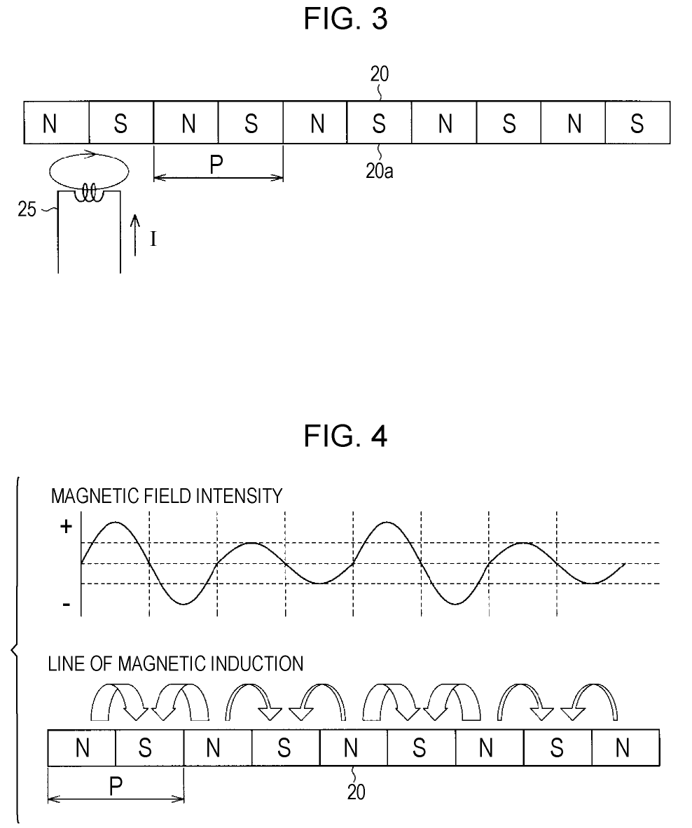

FIG. 3 is a diagram that explains an example of a method for polarizing the magnetic linear scale (20) of the magnetic linear encoder (22) according to the present embodiment of the invention. The polarization on the magnetic recording layer of the magnetic linear scale 20, which is formed at the edge portion of the endless paper-transport belt 16, is performed with the use of a polarizing apparatus. The polarizing apparatus is provided with a paper-transport driving roller (i.e., master roller) and a paper-transport driven roller (i.e., slave roller), each of which is not illustrated in the drawing. The paper-transport driving roller of the polarizing apparatus has substantially the same configuration as that of the paper-transport driving roller 13, which is provided in the belt paper-transport device 12 of the printer 11. The paper-transport driven roller of the polarizing apparatus has substantially the same configuration as that of the paper-transport driven roller 14, which is provided in the belt paper-transport device 12 of the printer 11. The endless paper-transport belt 16 is wound around the above-mentioned paper-transport driving roller and the above-mentioned paper-transport driven roller. The polarizing apparatus performs polarizing processing with the endless paper-transport belt 16 being wound around the above-mentioned paper-transport driving roller and the above-mentioned paper-transport driven roller.

As shown in FIG. 3, north (N) poles and south (S) poles are arrayed on the magnetic linear scale 20 in a regular alternate order with a predetermined regular pitch. Specifically, north (N) poles and south (S) poles are polarized on the magnetic linear scale 20 in a regular alternate order with a predetermined regular polarization pitch P in accordance with the intervals of (i.e., at intervals of) ink-drop ejecting positions in order to detect the position of the endless paper-transport belt 16. Therefore, it is possible to detect the position of a sheet of printing paper S. The polarizing apparatus is provided with a magnetic recording head 25 shown in FIG. 3. The magnetic poles N and S as well as magnetic field intensity are determined as a result of controlling the direction of an electric current I that flows in the magnetic recording head 25 and the amount of the electric current I. As a few examples of the sensor component of the magnetic recording head 25, a multi-value magnetic sensor that is capable of outputting multiple values such as a GMR (Giant Magneto Resistive Effect) sensor or an MR (Magneto Resistive Effect) sensor can be used without any limitation thereto. Other than the GMR sensor and the MR sensor described above, a Hall element or an MI (magnetic impedance) element can be used without any limitation thereto.

FIG. 4 is a two-part diagram that schematically illustrates an example of the intensity (i.e., strength) of a magnetic field that works on, or is applied to, the magnetic recording layer at the time of the polarization performed with the use of a magnetic recording head; and in addition thereto, FIG. 4 further schematically illustrates an example of the magnetic state (line of magnetic induction) of a magnetic linear scale. The direction of an electric current that flows in the magnetic recording head 25 and the amount thereof are controlled while rotating the endless paper-transport belt 16 at a predetermined speed V₀. Specifically, as illustrated in the upper-part diagram of FIG. 4, an electric current is controlled in such a manner that a magnetic field whose intensity changes in terms of amplitude in a periodic manner works on, or is applied to, a magnetic recording layer 20a of the magnetic linear scale 20. A polarization pattern is formed on the magnetic recording layer 20a of the magnetic linear scale 20. As illustrated in the lower-part diagram of FIG. 4, the polarization pattern that is formed on the magnetic recording layer 20a of the magnetic linear scale 20 has an alternate array of N poles and S poles. In such an array of the N and S poles, they alternate with each other for every one-half pitch. The amplitude of the magnetic field intensity changes in a cyclic pattern. Specifically, the magnetic field intensity switches over between a relatively large amplitude (fluctuation) pattern and a relatively small amplitude (fluctuation) pattern, which alternate with each other for every polarization pitch P. That is, the magnetic field intensity switches over between “strong” and “weak”, which alternate with each other for every polarization pitch P. The polarization pitch P, which is the alternate-array unit of detection target elements (i.e., magnetic poles N and S) of the magnetic linear scale 20, is determined on the basis of a belt operation/traveling speed at the time of printing performed by the printer 11 and on the basis of print resolution thereof. For example, the polarization pitch P is 35 μm or so for the print resolution of 720 dpi, or 70 μm or so for the print resolution of 360 dpi. Needless to say, the value of the polarization pitch P is not limited those mentioned above.

As a result of the reading of a magnetic pattern on the magnetic linear scale 20, the magnetic sensor 21 outputs a detection signal having a signal waveform whose cycle and amplitude corresponds to a fluctuating magnetic field intensity shown in the upper-part diagram of FIG. 4 because the line of magnetic induction behaves magnetically on the magnetic linear scale 20 as shown in the lower-part diagram of FIG. 4. Since the magnetic sensor 21 such as a GMR sensor or the like is used, it is possible to obtain an encoder output that has multi-value output amplitude. In short, it suffices if a detection signal whose amplitude changes in a certain cyclic pattern is obtained.

In the configuration of a pulse generation apparatus and an image formation apparatus (and a pulse generation method) according to the present embodiment of the invention, it is assumed that the movement amount per unit time (though not necessarily limited to time; hereafter may be referred to as “per-unit movement amount”) of the endless paper-transport belt 16, which is a non-limiting example of a “driving target medium” according to an aspect of the invention, equals to the polarization pitch P. That is, it is assumed herein that the unit of the driven amount of the endless paper-transport belt 16 equals to the polarization pitch P. Accordingly, the magnetic linear encoder 22 outputs a signal having a waveform each cycle thereof corresponds to the length in time of the movement of the endless paper-transport belt 16 for each polarization pitch P. Note that the driving target medium means a target object that is driven. The endless paper-transport belt 16 that has been subjected to polarization process explained above is wound around the aforementioned rollers as a component of the printer 11.

In the configuration of the printer 11 that is provided with the endless paper-transport belt 16, the controller 23 generates a print reference pulse PTS on the basis of an encoder signal, which has a signal waveform obtained from the magnetic pattern that is read out by the magnetic sensor 21 of the magnetic linear encoder 22. The recording head 19 ejects ink from/through the nozzles thereof at each rising edge (or at each falling edge) of the print reference pulse PTS, which constitutes ink-ejection timing. Each ink drop discharged from the recording head 18 lands on a sheet of printing paper S, which is the ink-ejection target medium. In this way, images, characters, and the like are printed on the sheet of printing paper S. In the foregoing description of the present embodiment of the invention, it is explained that an encoder output contains two signal-wave components one of which has larger amplitude in comparison with that of the other. However, the scope of the invention is not limited to such an exemplary configuration. As a non-limiting modification example thereof, an encoder output may contain three or more signal-wave components that differ in amplitude from one another. Such an encoder output containing three or more different signal-wave components are obtained if the value of an electric current that flows in the magnetic recording head 25 during the polarization process is switched over among three or more levels.

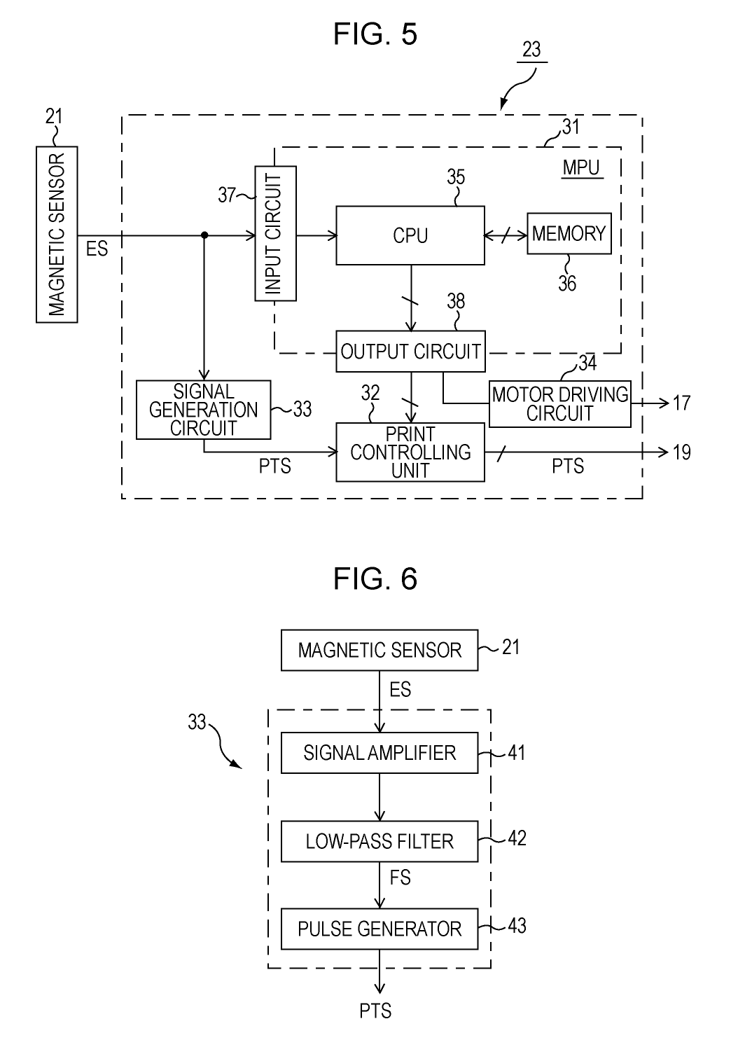

FIG. 5 is a block diagram that schematically illustrates an example of the electric configuration of the print controlling system inside the controller 23 according to the present embodiment of the invention. As shown in FIG. 5, the controller 23 is provided with a main controlling unit 31, a print controlling unit 32 that controls the printing operation of the recording head 19 under the control of the main controlling unit 31, a signal generation circuit 33 that generates a print reference pulse PTS on the basis of an encoder signal ES that is inputted from the magnetic sensor 21 of the magnetic linear encoder 22, and a motor driving circuit 34. The main controlling unit 31 can be formed as a MPU (Micro Processing Unit). Notwithstanding the above, the main controller unit 31 may be formed as a logic circuit or an analog circuit, though not limited thereto. The main controlling unit 31 is made up of a CPU (Central Processing Unit) 35, a memory 36, an input circuit 37, and an output circuit 38, though not necessarily limited thereto. The CPU 35 executes a program that is stored in the memory 36. The CPU 35 performs various kinds of processing while exchanging signals and/or data with the memory 36, the input circuit 37, and the output circuit 38. The memory 36 has a function of temporarily storing the computation result of the CPU 35, though the function of the memory 36 is not limited thereto.

The magnetic sensor 21 of the magnetic linear encoder 22 is electrically connected to the signal generation circuit 33 of the controller 23. An encoder signal ES that is outputted from the magnetic sensor 21 of the magnetic linear encoder 22 is inputted into the signal generation circuit 33 of the controller 23. In addition, the encoder signal ES that is outputted from the magnetic sensor 21 of the magnetic linear encoder 22 is also inputted into the input circuit 37 of the controller 23. On the basis of an encoder signal ES that is inputted from the magnetic sensor 21 of the magnetic linear encoder 22, the signal generation circuit 33 of the controller 23 generates a print reference pulse PTS having such a pulse cycle that makes it possible to offer print resolution in accordance with the operation/traveling speed of the endless paper-transport belt 16 (that is, paper-transport speed); and thereafter, the signal generation circuit 33 outputs the generated print reference pulse PTS. On the basis of the encoder signal ES that is inputted from the magnetic sensor 21 of the magnetic linear encoder 22 via the input circuit 37, the CPU 35 (of the controller 23) detects the operation/traveling speed of the endless paper-transport belt 16 (i.e., paper-transport speed). Then, the CPU 35 performs feedback control on the electric motor 17 through the motor driving circuit 34 on the basis of the detection result thereof.

As has already been explained above, the signal generation circuit 33 generates a print reference pulse PTS on the basis of the encoder signal ES received from the magnetic sensor 21 of the magnetic linear encoder 22 and then outputs the generated print reference pulse PTS to the print controlling unit 32. The print reference pulse PTS is forwarded from the print controlling unit 32 of the controller 23 to the recording head 19. The print controlling unit 32 of the controller 23 controls the ink-ejecting operation of the recording head 19 in such a manner that the recording head 19 discharges one ink drop for each predetermined unit movement amount of the endless paper-transport belt 16 in the direction of paper transportation. In the configuration of a pulse generation apparatus and an image formation apparatus (and a pulse generation method) according to the present embodiment of the invention, the cycle of the print reference pulse PTS is adjusted in such a manner that the per-unit movement amount of the endless paper-transport belt 16, which is a non-limiting example of a “driving target medium” according to an aspect of the invention, equals to the polarization pitch P at the time of the low-speed operation of the endless paper-transport belt 16 whereas the per-unit movement amount of the endless paper-transport belt 16 is twice as long as the polarization pitch P (=2P) at the time of the high-speed operation of the endless paper-transport belt 16.

The main controlling unit 31 sends image data to the print-controlling unit 32 through the output circuit 38. On the basis of the received print reference pulse PTS, the print controlling unit 32 controls the ejection timing of ink drops corresponding to a dot pattern that is in accordance with the received image data. As a non-limiting modification example of the illustrated exemplary configuration of the controller 23, a print reference pulse PTS that is outputted from the signal generation circuit 33 may not be supplied directly to the print controlling unit 32 but be inputted into the CPU 35 and then supplied to the print controlling unit 32 from the CPU 35. A combination of the magnetic linear encoder 22 according to the present embodiment of the invention and the signal generation circuit 33 according to the present embodiment of the invention corresponds to a pulse generation apparatus according to an aspect of the invention.

FIG. 6 is a block diagram that schematically illustrates an example of the inner configuration of the signal generation circuit 33 according to the present embodiment of the invention. As illustrated in FIG. 6, the signal generation circuit 33 is provided with a signal amplifier 41, a low-pass filter 42, and a pulse generator 43. The low-pass filter 42 is a non-limiting example of a switching section and a filtering section according to an aspect of the invention. The pulse generator 43 is a non-limiting example of a pulse generating section according to an aspect of the invention. The signal amplifier 41 amplifies a signal that is inputted from the magnetic sensor 21 of the magnetic linear encoder 22 and then outputs the amplified signal to the low-pass filter 42. The low-pass filter 42 has a function of cutting and/or reducing some frequency component of an input signal that is not lower than a predetermined frequency.

The printer 11 according to the present embodiment of the invention has two print modes that are different from each other in terms of printing speed. One of these two printing modes is a high-speed printing mode. The other of these two printing modes is a high-quality (i.e., low-speed) printing mode. In the high-speed printing mode, print speed is given priority over print quality. On the other hand, in the high-quality printing mode, print quality is given priority over print speed. The printing mode is determined on the basis of printing conditions, which are set by a user through input manipulation on a remote host apparatus that is connected to the printer 11 via a communication network. Note that the remote host apparatus is not illustrated in the drawing. For example, the high-speed printing mode is set if a user selects draft printing. The high-quality printing mode is set if a user selects photo printing. In the high-speed printing mode, the controller 23 controls, through the motor driving circuit 34, the rotation speed of the electric motor 17 in such a manner that the endless paper-transport belt 16 is driven/operated in a relatively high speed. On the other hand, in the high-quality printing mode, the controller 23 controls the rotation speed of the electric motor 17 through the motor driving circuit 34 in such a manner that the endless paper-transport belt 16 is driven/operated in a relatively low speed.

The low-pass filter 42 has such a circuit constant that it hardly reduces the amplitude of an encoder signal ES in the low-speed printing mode and substantially reduces the amplitude of an encoder signal ES in the high-speed printing mode.

The pulse generator 43 generates a print reference pulse PTS only at a point in time at which the value of an encoder signal “FS” (low-pass filter output), which is inputted from the low-pass filter 42, exceeds a predetermined threshold level. Specifically, the pulse generator 43 generates a print reference pulse PTS only at a point in time at which the value of the encoder signal FS that is inputted from the low-pass filter 42 goes over a threshold voltage level Vth↑ that is shown in FIGS. 9 and 10. The amplitude of an encoder signal FS that is supplied from the low-pass filter 42 to the pulse generator 43 decreases as the belt operation/traveling speed increases. In addition, the amplitude of an encoder signal FS that is supplied from the low-pass filter 42 to the pulse generator 43 decreases as the frequency of the encoder signal ES heightens. Accordingly, at the time of low-speed print operation in which the amplitude of the encoder signal FS takes a value that is relatively large, the level of a signal exceeds a threshold value for every rise (i.e., rising) thereof. For this reason, in the low-speed printing, the pulse generator 43 outputs a print reference pulse PTS that has the same cycle as that of the encoder signal ES. On the other hand, at the time of high-speed print operation in which the amplitude of the encoder signal FS takes a value that is relatively small, the level of a signal exceeds a threshold value for every other rise thereof. That is, at the time of high-speed print operation in which the amplitude of the encoder signal FS takes a relatively small value, a greater-amplitude-signal-wave component FSa only, which appears for every other rise of the encoder signal FS, goes over the threshold value. For this reason, in the high-speed printing, the pulse generator 43 outputs a print reference pulse PTS at each time when the endless paper-transport belt 16 travels twice as long distance as the polarization pitch P (=2P).

FIG. 8 is a graph that shows an example of the relationship between a belt operation/traveling speed and an encoder output gain according to the present embodiment of the invention. In this graph, the horizontal axis represents the belt operation/traveling speed, which is denoted as V. The vertical axis of this graph represents the encoder output gain. The encoder output gain, which depends on the setting of the cutoff frequency of the low-pass filter 42, is relatively large for a (relatively) low belt operation/traveling speed VL, whereas the encoder output gain is relatively small for a (relatively) high belt operation/traveling speed VH. Since the frequency of the encoder output under the high-speed operation of the endless paper-transport belt 16 has a higher frequency than that of the encoder output under the low-speed operation thereof, the output level thereof is relatively low as shown in the graph of FIG. 8. The low-pass filter 42 according to the present embodiment of the invention has filtering characteristics that has a steeper attenuation slope in the neighborhood of the cutoff frequency. In addition, according to the filtering characteristics of the low-pass filter 42 of the present embodiment of the invention, the output intensity thereof is very dependent on the belt operation/traveling speed V. That is, the circuit of the low-pass filter 42 according to the present embodiment of the invention is designed in such a manner that it has a downward inclination in the neighborhood of the border region between the low-speed belt operation and the high-speed belt operation; and therefore, in the neighborhood of the border between the low-speed belt operation region and the high-speed belt operation region, the encoder output gain gradually decreases as the belt operation/traveling speed V increases. Moreover, the high belt operation/traveling speed VH is set in the change region at which the encoder output gradually decreases. In the present embodiment of the invention in which the above-mentioned two belt operation/traveling speeds are available for printing, the low belt operation/traveling speed VL corresponds to the “minimum driven speed” according to an aspect of the invention, whereas the high belt operation/traveling speed VH corresponds to the “maximum driven speed” according to an aspect of the invention.

FIG. 9 is a diagram that schematically illustrates an example of the relationship between an encoder signal FS that is outputted from the low-pass filter 42 at the time of the low-speed operation of the endless paper-transport belt 16 and a print reference pulse PTS (i.e., ejection timing reference signal) that is outputted from the pulse generator 43 according to the present embodiment of the invention. FIG. 10 is a diagram that schematically illustrates an example of the relationship between an encoder signal FS that is outputted from the low-pass filter 42 at the time of the high-speed operation of the endless paper-transport belt 16 and a print reference pulse PTS (i.e., ejection timing reference signal) that is outputted from the pulse generator 43 according to the present embodiment of the invention. In each of FIGS. 9 and 10, the horizontal axis represents positions, or more specifically, belt operation/traveling positions. The frequency of an encoder signal FS obtained at the time of the high-speed operation of the endless paper-transport belt 16 is equal to the frequency of an encoder signal FS obtained at the time of the low-speed operation of the endless paper-transport belt 16 multiplied by a speed/velocity ratio (VH/VL).

Since the frequency of an encoder signal FS obtained at the time of the high-speed operation of the endless paper-transport belt 16 (which is shown in FIG. 10) is higher than the frequency of an encoder signal FS obtained at the time of the low-speed operation of the endless paper-transport belt 16 (which is shown in FIG. 9) the output level (i.e., amplitude) thereof under the high-speed belt operation is lower (i.e., smaller) than the output level (i.e., amplitude) thereof under the low-speed belt operation. For this reason, the signal strength (i.e., amplitude) of an encoder signal FS under the high-speed belt operation is smaller than the signal strength (i.e., amplitude) of an encoder signal FS under the low-speed belt operation.

The pulse generator 43 generates a pulse that has a rising edge corresponding to each intersection of the rising part of the signal-strength fluctuation of an encoder signal FS, which is inputted from the low-pass filter 42 into the pulse generator 43, and the threshold voltage level Vth↑. That is, each pulse rises at the point in time at which the encoder signal FS exceeds the threshold voltage level Vth↑. As has already been explained earlier, a polarization pattern is formed on the magnetic recording layer 20a of the magnetic linear scale 20. The polarization pattern that is formed on the magnetic recording layer 20a of the magnetic linear scale 20 has an alternate array of magnetic poles. The magnetic field intensity switches over between a relatively large amplitude (fluctuation) pattern and a relatively small amplitude (fluctuation) pattern, which alternate with each other for every polarization pitch P. Therefore, the encoder signal FS has, as two types of signal-wave components each of which corresponds to a polarization pitch P, the aforementioned greater-amplitude-signal-wave component FSa and a lesser-amplitude-signal-wave component FSb, each of which appears for every other rise of the encoder signal FS. The peak level of the greater-amplitude-signal-wave component FSa under the low-speed belt operation is denoted as A1max. The peak level of the lesser-amplitude-signal-wave component FSb under the low-speed belt operation is denoted as B1max. The peak level of the greater-amplitude-signal-wave component FSa under the high-speed belt operation is denoted as A2max. The peak level of the lesser-amplitude-signal-wave component FSb under the high-speed belt operation is denoted as B2max. Under these assumptions, the threshold voltage level Vth↑ is set at a value that satisfies the following mathematical formulae.

Under the low-speed belt operation, the following set of mathematical expressions holds true.

Threshold Voltage Level Vth↑<A1max; and Vth↑<B1max (1)

Under the high-speed belt operation, the following set of mathematical expressions holds true.

Threshold Voltage Level Vth↑<A2max; and Vth↑>B2max (2)

That is, the threshold voltage level Vth↑ according to the present embodiment of the invention is set at a value that is lower than both of the peak level A1max of the greater-amplitude-signal-wave component FSa under the low-speed belt operation and the peak level B1max of the lesser-amplitude-signal-wave component FSb under the low-speed belt operation (refer to FIG. 9). In addition, the threshold voltage level Vth↑ according to the present embodiment of the invention is set at a value between the peak level A2max of the greater-amplitude-signal-wave component FSa under the high-speed belt operation and the peak level B2max of the lesser-amplitude-signal-wave component FSb under the high-speed belt operation (refer to FIG. 10).

More, the threshold voltage level Vth↑ according to the present embodiment of the invention has a hysterisis. That is, in addition to the pulse-rising threshold voltage level Vth↑, a pulse-falling threshold voltage level Vth↓ is predetermined. The pulse-falling threshold voltage level Vth↓ is set at a value that is smaller than the pulse-rising threshold voltage level Vth↑. At each time when the signal strength of the encoder signal FS goes over the pulse-rising threshold voltage level Vth↑, the print reference pulse PTS rises. Once after the print reference pulse PTS has risen, it does not fall even when the signal strength of the encoder signal FS goes under the pulse-rising threshold voltage level Vth↑. That is, the print reference pulse PTS does not fall until the signal strength of the encoder signal FS reaches the pulse-falling threshold voltage level Vth↓. At each time when the signal strength of the encoder signal FS goes under the pulse-falling threshold voltage level Vth↓, the print reference pulse PTS falls. The threshold voltage level Vth↑ according to the present embodiment of the invention has a hysterisis as explained above. Thanks to such a hysterisis, the encoder signal FS is less susceptible to noise. If there are almost no adverse noise effects, or if noise rejection (i.e., denoising or noise cancellation) is performed, it is possible to narrow the hysterisis range of a threshold voltage. Or, in such a case, it is possible to omit hysterisis. That is, in a case where there are almost no adverse noise effects or where noise rejection is performed, the pulse-rising threshold voltage level Vth↑ only may be set without setting the pulse-falling threshold voltage level Vth↓.

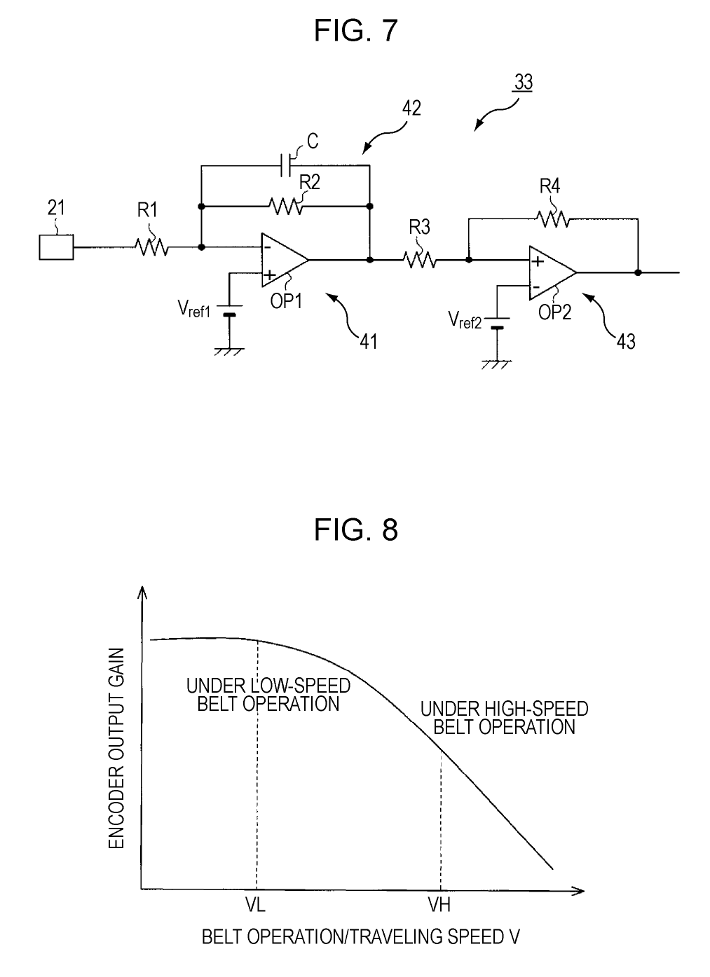

FIG. 7 is an electric circuit diagram that schematically illustrates an example of the circuit configuration of the signal generation circuit 33 according to the present embodiment of the invention. The output terminal of the magnetic sensor 21 of the magnetic linear encoder 22 is electrically connected to the negative input terminal of an operational amplifier OP1 with a resistor R1 being provided therebetween. A reference voltage Vref1 is inputted into the positive input terminal of the operational amplifier OP1. The output terminal of the operational amplifier OP1 is electrically connected to the negative input terminal thereof via a resistor R2, which is provided between the output terminal and the negative input terminal. With such an electric configuration, an output voltage Vout that is outputted from the output terminal of the operational amplifier OP1 returns to the negative input terminal thereof. An inverting amplifier (i.e., inverting amplification circuit) that includes the operational amplifier OP1 constitutes the signal amplifier 41 according to the present embodiment of the invention. A capacitor C is provided in parallel with the resistor R2. That is, the capacitor C is added to the inverting amplification circuit. These capacitor C and the resistor R2 make up the low-pass filter 42 according to the present embodiment of the invention.

The output terminal of the operational amplifier OP1 is electrically connected to the positive input terminal of another operational amplifier OP2 via a resistor R3, which is provided therebetween. A reference voltage Vref2 is inputted into the negative input terminal of the operational amplifier OP2. The output terminal of the operational amplifier OP2 is electrically connected to the positive input terminal thereof via a resistor R4, which is provided between the output terminal and the positive input terminal, for positive feedback. That is, it is configured as a hysterisis circuit, which constitutes the pulse generator 43 according to the present embodiment of the invention. The value of each of the pulse-rising threshold voltage level Vth↑ and the pulse-falling threshold voltage level Vth↓ is determined as a result of the setting of the resistance values of the resistors R3 and R4 as well as the value of the reference voltage Vref2.

As has already been explained above, each signal-wave component of an encoder signal FS, that is, the aforementioned greater-amplitude-signal-wave component FSa and the afore-mentioned lesser-amplitude-signal-wave component FSb, each of which appears for every other rise of the encoder signal FS, exceeds the threshold voltage level Vth↑ at the time of the low-speed operation of the endless paper-transport belt 16, which is shown in FIG. 9. Therefore, the signal generation circuit 33 having the circuit configuration explained above generates a print reference pulse PTS so as to correspond to each signal-wave component of an encoder signal FS at the time of the low-speed belt operation. As a consequence thereof, under the low-speed belt operation, a print reference pulse PTS appears at each time when the endless paper-transport belt 16 travels by one polarization pitch P. Thus, the recording head 19 performs printing with high resolution. On the other hand, at the time of the high-speed operation of the endless paper-transport belt 16 (refer to FIG. 10), it is only the greater-amplitude-signal-wave component FSa that exceeds the threshold voltage level Vth↑. Therefore, at the time of the high-speed belt operation, the signal generation circuit 33 having the circuit configuration explained above generates a print reference pulse PTS corresponding not to both of two signal-wave components of an encoder signal FS but to the greater-amplitude-signal-wave component FSa only, which appears for every other rise of the encoder signal FS. As a consequence thereof, under the high-speed belt operation, a print reference pulse PTS appears at each time when the endless paper-transport belt 16 travels by two polarization pitches (=2P). Thus, the recording head 19 performs printing with low resolution. That is, the printer 11 performs printing with relatively high resolution at the time of the low-speed belt operation. At the time of the high-speed belt operation, the printer 11 performs printing with relatively low resolution.

The input circuit 37 shown in FIG. 5 has a built-in pulse generation circuit that has a configuration similar to that of the pulse generator 43 of the signal generation circuit 33. Specifically, except that the built-in pulse generation circuit of the input circuit 37 is not provided with a low-pass filter (42), it has the same configuration as that of the pulse generator 43 of the signal generation circuit 33. An encoder signal ES that is supplied from the magnetic sensor 21 of the magnetic linear encoder 22 is inputted into the CPU 35 of the controller 23 via the input circuit 37 thereof as a pulse signal having the same cycle as that of the encoder signal ES. The threshold voltage level Vth↑ of the built-in pulse generation circuit inside the input circuit 37 is set at such a value that each signal-wave component of an encoder signal FS exceeds the threshold voltage level Vth↑ at the time of both of the low-speed belt operation and the high-speed belt operation. That is, regardless of whether the endless paper-transport belt 16 is operated in a low speed or in a high speed, the built-in pulse generation circuit of the input circuit 37 generates a pulse having the same cycle as an encoder signal ES. The CPU 35 counts the pulses by means of a pulse counter so as to detect the traveling position of the endless paper-transport belt 16. By this means, the CPU 35 performs feedback control on the electric motor 17 in such a manner that it (i.e., the electric motor 17) is driven at a target speed that is in accordance with the current printing mode.

As explained above in detail, a pulse generation apparatus, an image formation apparatus, and a pulse generation method according to the present embodiment of the invention offers the following advantageous effects.

(1) The magnetic linear encoder 22 is capable of outputting an encoder signal ES whose signal strength switches over between a relatively large amplitude fluctuation and a relatively small amplitude fluctuation, which alternate with each other at each time when the endless paper-transport belt 16 travels by one polarization pitch P. The encoder signal ES passes through the low-pass filter 42 that has a cutoff frequency in the neighborhood of the encoder-signal-frequency border between the low-speed belt operation region (i.e., domain) and the high-speed belt operation region. An encoder output gain takes a smaller value during the high-speed belt operation than that during the low-speed belt operation. Since the encoder signal ES passes through the low-pass filter 42, the amplitude of the (filter-output) encoder signal FS under the high-speed belt operation is smaller than that under the low-speed belt operation. In addition, the pulse generator 43 generates such a print reference pulse PTS that rises at each point in time at which the encoder signal FS exceeds the threshold voltage level Vth↑. Therefore, it is possible to generate a print reference pulse PTS that offers different print resolutions (i.e., different resolving powers). That is, under the low-speed belt operation, one pulse is outputted at each time when the endless paper-transport belt 16 travels by one polarization pitch P. On the other hand, under the high-speed belt operation, one pulse is outputted at each time when the endless paper-transport belt 16 travels by two polarization pitches 2P. In comparison with the aforementioned related-art configuration that is disclosed in JP-A-5-318869, which has a plurality of polarization lines as well as a plurality of magnetic sensors, or in comparison with another related-art configuration that uses a frequency divider circuit, a pulse generation apparatus, an image formation apparatus, and a pulse generation method according to the present embodiment of the invention make it possible to generate a print reference pulse PTS that offers different print resolutions in accordance with a paper-transport speed with a simpler structure. Thus, if a pulse generation apparatus, an image formation apparatus, and a pulse generation method according to the present embodiment of the invention are adopted, with a simpler structure, it is possible to perform printing with relatively low resolution at a relatively high paper-transport speed in the high-speed printing mode and to perform printing with relatively high resolution at a relatively low paper-transport speed in the high-quality (i.e., low-speed) printing mode.

(2) The low-pass filter 42 has such a circuit constant that it has a certain inclination with which an encoder output gain gradually changes as the belt operation/traveling speed V changes at a change region. The low-pass filter 42 has a cutoff frequency in the neighborhood of the border between the low belt operation/traveling speed VL and the high belt operation/traveling speed VH. Therefore, it is possible to set the high belt operation/traveling speed VH that is applied at the time of the high-speed printing inside the change region. Thus, it is further possible to set signal-wave amplitude during the high-speed printing operation smaller than signal-wave amplitude during the low-speed printing operation.

(3) Since the encoder according to the present embodiment of the invention is configured as the magnetic linear encoder 22, it is possible to form the magnetic linear scale 20 by forming a polarization pattern on the magnetic recording layer 20a thereof so as to have an alternate array of magnetic poles in such a manner that the magnetic field intensity switches over between a relatively large amplitude (fluctuation) pattern and a relatively small amplitude (fluctuation) pattern, which alternate with each other for every polarization pitch P. Since it is formed as a magnetic linear encoder, it is possible to achieve a high signal precision with a simple manufacturing process. If it is formed as, for example, an optical encoder, complex adjustment of the opening shapes of slits and the opening spaces thereof is required in order to generate a signal wave whose amplitude changes in a cyclic pattern. Specifically, if it is formed as an optical encoder, it is necessary to adjust the opening shapes of slits and the opening areas thereof so that the amount of light received by an optical sensor(s) switches over in an alternate manner for each cycle (i.e., pitch P). Such optical adjustment makes the production of the encoder less simple. Furthermore, if it is formed as an optical encoder, there is a risk that light could diffuse and/or that outside light (indoor light) could leak into the optical sensor, which results in the loss of precision.

### Second Embodiment

In the following description, a non-limiting example of the modified configuration of the signal generation circuit 33, which generates a print reference pulse PTS, is explained. A signal generation circuit according to the present embodiment of the invention is not provided with the low-pass filter 42, which is a non-limiting example of a switching section according to an aspect of the invention.

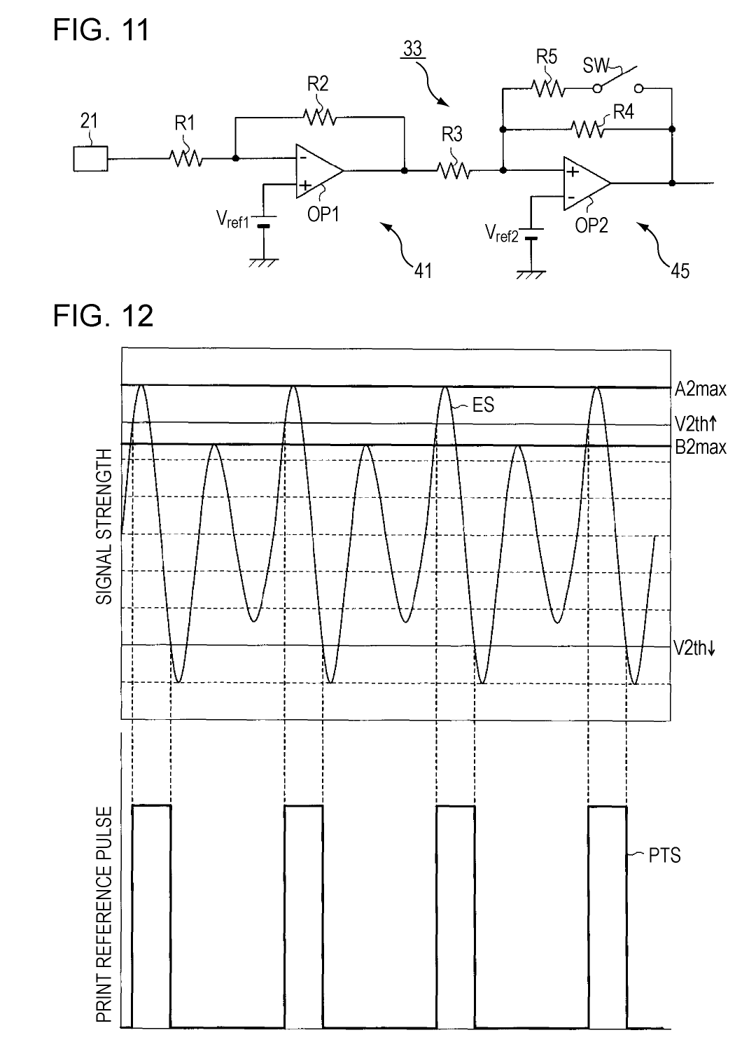

As shown in FIG. 11, the aforementioned capacitor C, which is a component of the signal generation circuit 33 according to the first exemplary embodiment of the invention (refer to FIG. 7), is omitted from the circuit configuration of a signal generation circuit according to the second exemplary embodiment of the invention. Therefore, the signal generation circuit according to the present embodiment of the invention is not provided with the low-pass filter 42. An inverting amplifier that includes the operational amplifier OP1 constitutes the signal amplifier 41 according to the present embodiment of the invention. In the circuit configuration of a pulse generator 45, a resistor R5 and a switch SW are connected in parallel with the aforementioned resistor R4, which constitutes a hysterisis circuit. The switch SW is formed as, for example, an analog switch or a transistor, though not limited thereto. The set value of a threshold voltage level can be changed as the switch SW is turned ON/OFF. For example, the threshold voltage level is set at Vth↑ when the switch is in a closed state. The threshold voltage level is set at V2th↑ when the switch is in an open state. The threshold voltage level V2th↑ is higher than the threshold voltage level Vth↑ (V2th↑>Vth↑)

Since the signal generation circuit according to the present embodiment of the invention is not provided with the low-pass filter 42, the amplitude peak value of an encoder signal ES under the low-speed belt operation is substantially the same as the amplitude peak value of an encoder signal ES under the high-speed belt operation (A1max=A2max, B1max=B2max). The threshold voltage level is set at a value that satisfies the mathematical formulae (1) and (2) explained in the foregoing first exemplary embodiment of the invention. Note that, however, the threshold voltage level is switched over depending on the switching state in the present embodiment of the invention. A pulse signal having a cycle corresponding to the belt operation/traveling speed is inputted into the switch SW. The pulse signal is generated in a built-in pulse generation circuit of the input circuit 37 on the basis of an encoder signal ES. The switch SW is closed if the cycle of the input pulse signal indicates a value corresponding to the low-speed belt operation. The switch SW is opened if the cycle of the input pulse signal indicates a value corresponding to the high-speed belt operation. In the modified configuration of the signal generation circuit 33 according to the present embodiment of the invention, the switch SW changes over the value of the threshold voltage level depending on the belt operation/traveling speed. The switch SW is a non-limiting example of a “switching section” and a “threshold switching section” according to an aspect of the invention.

Under the low-speed belt operation, an encoder signal ES with almost no amplitude attenuation is inputted into the pulse generator 45. For example, under the low-speed belt operation, an encoder signal ES having substantially the same level as that of an encoder signal FS shown in FIG. 9 is inputted into the pulse generator 45. The switch SW is closed under the low-speed belt operation. Accordingly, the threshold voltage level is set at Vth↑, that is, the same level as that of FIG. 9. As a result thereof, the signal generation circuit according to the present embodiment of the invention outputs a print reference pulse PTS that has the same cycle as that of the encoder signal ES (refer to FIG. 9).

On the other hand, under the high-speed belt operation, an encoder signal ES shown in FIG. 12 is inputted into the pulse generator 45. The switch SW is opened under the high-speed belt operation. Accordingly, the threshold voltage level is set at V2th↑ as shown in FIG. 12, which satisfies the set of mathematical expressions (2) explained in the foregoing first exemplary embodiment of the invention. As a result thereof, the signal generation circuit according to the present embodiment of the invention outputs a print reference pulse signal PTS corresponding to every other rise and fall of the encoder signal ES (refer to FIG. 12).

As explained above in detail, a pulse generation apparatus, an image formation apparatus, and a pulse generation method according to the present embodiment of the invention offers the following advantageous effects.

(4) The threshold voltage level is switched over between Vth↑ and V2th↑ on the basis of the closed/open state of the switch SW, which makes it possible to achieve a simple structure. Therefore, it is possible to generate a print reference pulse PTS that offers print resolution corresponding to the belt operation/traveling speed without any necessity to provide a frequency divider circuit.

Although a pulse generation apparatus, an image formation apparatus, and a pulse generation method having distinctively unique features of the present invention are described above while explaining preferred exemplary embodiments thereof, the invention should be in no case interpreted to be limited to the specific embodiments described above. The invention may be modified, altered, changed, adapted, and/or improved within a range not departing from the gist and/or spirit of the invention apprehended by a person skilled in the art from explicit and implicit description made herein, where such a modification, an alteration, a change, an adaptation, and/or an improvement is also covered by the scope of the appended claims. The followings are non-limiting examples of a modification, an alteration, a change, an adaptation, and/or an improvement of the preferred exemplary embodiments described above.

### VARIATION EXAMPLE 1

The filtering section according to an aspect of the invention is not limited to the low-pass filter 42. For example, a band-pass filter or a high-pass filter may be used in place of the low-pass filter 42. That is, it suffices if a cutoff frequency is set in such a manner that an encoder output gain that is obtained under the low-speed belt operation and an encoder output gain that is obtained under the high-speed belt operation differ from each other. For example, if a band-pass filter is used in place of the low-pass filter 42, the cutoff frequency thereof is set at a region (i.e., domain) between the low belt operation/traveling speed (VL) and the high belt operation/traveling speed (VH). In addition, the circuit constant of the band-pass filter is set in such a manner that it has a downward inclination with which an encoder output gain gradually decreases as the belt operation/traveling speed V increases at a change region. If higher resolution (i.e., higher resolving power) is required under the high-speed belt operation than that is required under the low-speed belt operation, a high-pass filter is used as the filtering section according to an aspect of the invention. In addition, the circuit constant of the high-pass filter is set in such a manner that it has an upward inclination with which an encoder output gain gradually decreases as the belt operation/traveling speed V decreases at a change region.

### VARIATION EXAMPLE 2

Both of the low belt operation/traveling speed VL and the high belt operation/traveling speed VH may be set in the change region. For example, a high-pass filter can be used as the filtering section according to an aspect of the invention in some application other than printing; in such an exemplary application, the low belt operation/traveling speed VL is set in a change region so that an encoder output gain gradually decreases as a driving target medium according to an aspect of the invention is driven at a faster operation/traveling speed.

### VARIATION EXAMPLE 3

In each of the foregoing exemplary embodiments of the invention, it is explained that a polarization pattern that is formed on the magnetic recording layer 20a of the magnetic linear scale 20 has an alternate array of two magnetic poles and further explained that the magnetic field intensity thereof switches over between two (i.e., relatively large one and relatively small one) amplitude fluctuation patterns that alternate with each other. However, the scope of the invention is not limited to such an exemplary configuration. For example, the magnetic field intensity thereof may switch over between three, four, or more amplitude fluctuation patterns. If so configured, it is possible to generate a print reference pulse PTS that offers print resolutions that differ from one another so as to correspond to three, four, or more belt operation/traveling speeds. For example, a polarization pattern may be formed on the magnetic recording layer 20a of the magnetic linear scale 20 in such a manner that the magnetic field intensity thereof changes in the periodic order of “strong (i.e., large magnetic amplitude), weak, medium, and then, weak again”. Under the low-speed belt operation, each of four signal-wave components corresponding to the “strong, weak, medium, and weak” cyclic pattern exceeds a threshold voltage level. Under the medium-speed belt operation, two of four signal-wave components corresponding to the “strong” and “medium” exceed the threshold voltage level. Under the high-speed belt operation, one of four signal-wave components corresponding to the “strong” only exceeds the threshold voltage level. Thus, in the modification example explained above, it is possible to generate a print reference pulse PTS that offers print resolutions that differ from one another so as to correspond to three belt operation/traveling speeds; that is, printing is performed with one-pitch (1P) resolution under the low-speed belt operation; printing is performed with two-pitch (2P) resolution under the medium-speed belt operation; and printing is performed with four-pitch (4P) resolution under the high-speed belt operation.

### VARIATION EXAMPLE 4

The second exemplary embodiment of the invention explained above may be modified in such a manner that the CPU judges whether the endless paper-transport belt 16 is currently being operated in a low speed or in a high speed on the basis of a pulse signal and then performs the switching control of the switch SW on the basis of the result of such a judgment. Depending on applications, a pulse may offer higher resolution for faster traveling of a driving target medium according to an aspect of the invention.

### VARIATION EXAMPLE 5

The mounting position of a magnetic or non-magnetic scale of an encoder according to an aspect of the invention is not limited to a paper-transport belt. For example, a non-linear rotary magnetic scale may be provided on the end face of any roller that makes up a part/component of the belt paper-transport device 12. Or, alternatively, a scale may be provided on another driven target medium that is provided on the power transmission line between an electric motor, which is a power source, and a motor-drive target medium, which is driven by the electric motor.

### VARIATION EXAMPLE 6

Means for transporting a transport target medium such as a sheet of printing paper or the like is not limited to the paper-transport belt 16. That is, the invention can be applied to, in addition to a belt target-transport system described above, other alternative target-transport system. For example, the invention is applicable to such a printer that has a roller-based paper-transport device having a plurality of roller devices. Each of the plurality of roller devices is made up of a pair of a paper-transport driving roller and a paper-transport driven roller. The plurality of roller devices is provided at more than one place on a paper-transport channel/route. A magnetic scale can be provided on the end face of such a roller. Or, a rotary-encoder-type magnetic scale may be provided on the rotation axis of such a roller or on the rotation axis of other power transmission system. Or, in the case of a belt paper-transport system that is used in a line printer, a plurality of belts may be stretched so as to form a staggered array pattern between one roller that is provided at an upstream-side position of a paper-transport channel/route when viewed along the direction of paper transportation and another roller that is provided at a downstream-side position of the paper-transport channel/route when viewed along the direction of paper transportation.

### VARIATION EXAMPLE 7

The type of a printer to which a pulse generation apparatus according to an aspect of the invention can be applied is not limited to a line printer. For example, a pulse generation apparatus according to an aspect of the invention may be applied to a serial printer, which performs printing while moving (i.e., scanning) its recording head in the paper-width direction. That is, a driving target medium according to an aspect of the invention is not limited to any part, component, or member of the above-mentioned means for transporting a transport target medium. For example, a driving target medium according to an aspect of the invention may be any moving means such as a carriage on which a recording head is mounted. The following is a non-limiting example of such a modified configuration. A linear encoder is provided in parallel with the traveling/movement path of the carriage. An encoder signal ES that is outputted from a sensor, which moves together with the carriage, is inputted into the signal generation circuit (33) according to any of the foregoing first and second exemplary embodiments of the invention. Then, the signal generation circuit (33) generates a print reference pulse PTS on the basis of the encoder signal ES.

### VARIATION EXAMPLE 8

An encoder according to an aspect of the invention (e.g., linear encoder, rotary encoder) is not limited to magnetic one. For example, it may be formed as an optical encoder. The optical encoder should be formed as follows. A plurality of slits is formed in a scale with a predetermined pitch. The opening shapes of these slits and the opening areas thereof are adjusted so that the amount of light, which is emitted from a light source such as a light-emitting element and then passes through the slit so as to be received by a photo-sensor, changes over in a periodic manner. By this means, it is possible to obtain an encoder signal ES whose amplitude changes in a cyclic pattern.

### VARIATION EXAMPLE 9

In the foregoing description of exemplary embodiments of the invention, it is explained that an image formation apparatus according to an aspect of the invention is embodied as an ink-jet recording apparatus, which is an example of a variety of fluid ejecting apparatuses. However, the scope of the invention is not limited to such an exemplary configuration. For example, the invention is also applicable to a variety of other fluid ejecting apparatuses that ejects or discharges various kinds of fluid other than ink. The invention is further applicable to a fluid ejecting apparatus that ejects a liquid/liquefied matter/material that is made as a result of dispersion or mixture of particles of functional material(s) into/with liquid. The invention is further applicable to a fluid ejecting apparatus that ejects a gel substance. The invention is further applicable to a fluid ejecting apparatus that ejects a semi-solid or solid substance that can be ejected as a fluid. A non-limiting example thereof is any powder or a granular matter/material that contains toner. It should be noted that the scope of the invention is not limited to those enumerated above. In addition to an ink-jet recording apparatus described in the foregoing exemplary embodiments of the invention, a fluid ejecting apparatuses to which the invention is applicable encompasses a wide variety of other types of apparatuses that ejects liquid or fluid in which, for example, a color material (pixel material) or an electrode material is dispersed or dissolved, though not necessarily limited thereto. Herein, the color material may be, for example, one that is used in the production of color filters for a liquid crystal display device or the like. The electrode material (i.e., conductive paste) may be, though not limited thereto, one that is used for electrode formation of an organic EL display device, a surface/plane emission display device (FED), and the like. Moreover, the invention is applicable to and thus can be embodied as a liquid ejecting apparatus that ejects liquid of a transparent resin such as an ultraviolet ray curing resin or the like onto a substrate so as to form a micro hemispherical lens (optical lens) that is used in an optical communication element or the like. Furthermore, the invention is applicable to and thus can be embodied as a liquid ejecting apparatus that ejects an etchant such as acid or alkali that is used for the etching of a substrate or the like. Further in addition, the invention is applicable to and thus can be embodied as a fluid ejecting apparatus that ejects a gel fluid (e.g., physical gel). These various kinds of fluid ejecting apparatuses including liquid ejecting apparatuses form a variety of patterns such as a wiring pattern, an electrode pattern, a pixel pattern, an etching pattern, and an array pattern without any limitation thereto as a result of the ejection of a variety of fluids (dots) onto an ejection target. In the context of this specification, an image that is formed by an image formation apparatus according to an aspect of the invention, which can be reworded as an image pattern or a pattern image, should be understood as a non-limiting example of such a variety of patterns. In the description of this specification and the recitation of appended claims, the term “fluid” is defined as a broad generic concept that encompasses a variety of fluid matter/material/substance that includes but not limited to liquid matter/material/substance. Only one exception thereof is “gas-only” fluid (i.e., fluid that is made up of gas only). For example, the fluid includes, without any limitation thereto, inorganic solvent, organic solvent, solution, liquid resin, and liquid metal (e.g., metal melt). The fluid further includes, without any limitation thereto, any particulate matter/material including but not limited to any powder or a granular matter/material (as explained above). In each of the foregoing first and second embodiments of the invention, an ink-jet printer (11) is taken as an example of an image formation apparatus according to an aspect of the invention. However, needless to say, the scope of the invention is not limited to such an exemplary application. As a non-limiting modification example thereof, an image formation apparatus according to an aspect of the invention may be embodied and/or implemented as a dot impact printer, a thermal transfer printer, or a laser printer, though not limited thereto.

### VARIATION EXAMPLE 10

The type of an apparatus to which a pulse generation apparatus according to an aspect of the invention can be applied is not limited to an image formation apparatus such as a printer or the like. A pulse generation apparatus according to an aspect of the invention can be applied to a wide variety of apparatuses that requires a pulse that offers resolutions different from one another so as to correspond to the driven speed of a driving target medium according to an aspect of the invention. Such a pulse is generated on the basis of an encoder signal that is outputted by a sensor that performs detection on a linear or non-linear scale in accordance with the moving speed of the driving target medium. For example, a pulse generation apparatus according to an aspect of the invention can be applied to a work machining apparatus such as a punching apparatus that punches holes with a predetermined pitch in a workpiece under transportation. Or, as another example of a wide variety of applications thereof, a pulse generation apparatus according to an aspect of the invention can be used for a chip mounting apparatus that mounts electronic parts/components with a predetermined pitch on a board under transportation.

The following is one aspect of the technical concept of the invention that can be understood from the foregoing exemplary embodiments of the invention and variation examples thereof described above.

(1) The pulse generation apparatus according to claim 5, wherein the threshold switching section performs a threshold switchover in such a manner that the number of signal wave(s) that exceed the threshold decreases as the driven speed of the driving target medium increases.

What is claimed is:

1. A pulse generation apparatus comprising:
an encoder that outputs an encoder signal in a cycle corresponding to each driven operation of a driving target medium by a drive amount per unit, the pulse generation apparatus generating a pulse on the basis of the encoder signal that is outputted by the encoder, the amplitude of the signal changing in a cyclic manner;
a switching section that receives the encoder signal that is outputted from the encoder and then switches at least one either of the amplitude of the signal and a threshold depending on the driven speed of the driving target medium so as to change the number of signal waves that exceed the threshold depending on the driven speed of the driving target medium; and
a pulse generating section that generates a pulse having the same cycle as that of the signal wave that exceeds the threshold.

2. The pulse generation apparatus according to claim 1, wherein the switching section is a filtering section whose cutoff frequency is set in such a manner that signal-output gain changes in accordance with the frequency of the signal; and the signal that is outputted from the encoder passes through the filtering section so that the amplitude of the signal is switched over depending on the driven speed of the driving target medium.

3. The pulse generation apparatus according to claim 2, wherein the filtering section has such a circuit constant that the signal-output gain changes gradually in accordance with the driven speed of the driving target medium at a change region; and at least either one of the minimum driven speed of the driving target medium and the maximum driven speed of the driving target medium is set in the change region.

4. The pulse generation apparatus according to claim 2, wherein the filtering section has such a cutoff frequency that the signal-output gain obtained at the time of the high-speed driven operation of the driving target medium is larger than the signal-output gain obtained at the time of the low-speed driven operation of the driving target medium.

5. The pulse generation apparatus according to claim 1, wherein the switching section is a threshold switching section that switches the threshold depending on the driven speed of the driving target medium.

6. The pulse generation apparatus according to claim 1, wherein the encoder is a magnetic encoder that has a magnetic scale and a magnetic sensor; a polarization pattern whose magnetic field intensity changes in a cyclic manner is formed on the magnetic scale; and the magnetic sensor performs magnetic detection on the magnetic scale and then outputs an encoder signal including signal waves whose amplitudes correspond to the magnetic field intensity of the polarization pattern.

7. An image formation apparatus comprising:
a transporting section that transports an image-formation target medium;
a recording section that performs recording on the image-formation target medium; and
the pulse generation apparatus according to claim 1, wherein the encoder that makes up a part of the pulse generation apparatus is capable of detecting either the transport of the transporting section or the movement of the recording section; and
the image formation apparatus uses a pulse that is outputted from the pulse generation apparatus as a reference signal for determining the recording timing of the recording section.

8. A pulse generation method for generating a pulse on the basis of an encoder signal that is outputted by an encoder, the encoder outputting the encoder signal in a cycle corresponding to each driven operation of a driving target medium by a drive amount per unit, the pulse generation method comprising:
inputting the signal whose amplitude changes in a cyclic manner from the encoder;
switching at least either one of the amplitude of the signal and a threshold depending on the driven speed of the driving target medium so as to change the number of signal waves that exceed the threshold depending on the driven speed of the driving target medium; and
generating a pulse that has the same cycle as that of the signal wave that exceeds the threshold.
